(19) United States
(12) Patent Application Publication
(10) Pub. No.: US 2024/0429272 A1
(43) Pub. Date: Dec. 26, 2024

(54) SILICON CARBIDE SEMICONDUCTOR DEVICES WITH SUPERJUNCTIONS

(71) Applicant: Wolfspeed, Inc., Durham, NC (US)

(72) Inventor: Rahul R. POTERA, Apex, NC (US)

(21) Appl. No.: 18/213,500

(22) Filed: Jun. 23, 2023

(51) Int. Cl. H01L 29/06; H01L 29/16; H01L 29/66; H01L 29/808

(52) U.S. Cl. CPC H01L 29/0634; H01L 29/1608; H01L 29/66068; H01L 29/8083

(57) ABSTRACT

A semiconductor device includes a substrate and an epitaxial structure on the substrate. The epitaxial structure includes a drift region and a mesa stripe on the drift region. The mesa stripe includes a channel region on the drift region, a source region on the channel region, and sidewall gate regions on opposite sides of the channel region. The channel region and the source region have a first conductivity type and the sidewall gate regions have a second conductivity type opposite the first conductivity type. The drift region includes a central pillar having the first conductivity type and outer pillars on opposite sides of the central pillar. The outer pillars have the first conductivity type, and the outer pillars and the central pillar form a superjunction structure in the drift region. Related methods are also disclosed.

### FIELD

The present disclosure relates to power semiconductor devices and, more particularly, to power semiconductor devices having superjunction structures and to methods of fabricating such devices.

### BACKGROUND

Power semiconductor devices are used to carry large currents and support high voltages. A wide variety of power semiconductor devices are known in the art including, for example, power Metal Oxide Semiconductor Field Effect Transistors (“MOSFET”), Junction Field Effect Transistors (“JFET”), bipolar junction transistors (“BJTs”), Insulated Gate Bipolar Transistors (“IGBT”), Schottky diodes, Junction Barrier Schottky (“JBS”) diodes, merged p-n Schottky (“MPS”) diodes, Gate Turn-Off Transistors (“GTO”), MOS-controlled thyristors and various other devices. These power semiconductor devices are generally fabricated from monocrystalline silicon semiconductor material, or, more recently, from silicon carbide or gallium nitride based semiconductor materials.

Power semiconductor devices can have a lateral structure or a vertical structure. In a device having a lateral structure, the terminals of the device (e.g., the drain, gate and source terminals for a power MOSFET device) are on the same major surface (i.e., top or bottom) of a semiconductor layer structure. In contrast, in a device having a vertical structure, at least one terminal is provided on each major surface of the semiconductor layer structure (e.g., in a vertical MOSFET device, the source may be on the top surface of the semiconductor layer structure and the drain may be on the bottom surface of the semiconductor layer structure). The semiconductor layer structure may or may not include an underlying substrate. Herein, the term “semiconductor layer structure” refers to a structure that includes one or more semiconductor layers such as semiconductor substrates and/or semiconductor epitaxial layers.

A conventional silicon carbide power device typically has a silicon carbide substrate, such as a silicon carbide wafer having a first conductivity type (e.g., an n-type substrate), on which an epitaxial layer structure having the first conductivity type (e.g., n-type) is formed. This epitaxial layer structure (which may comprise one or more separate layers) functions as a drift region of the power semiconductor device. The active region may be formed on and/or in the drift region. The active region acts as a main junction or region for blocking voltage in the reverse bias direction and providing current flow in the forward bias direction. The device may also have an edge termination region adjacent the active region. One or more power semiconductor devices may be formed on the substrate, and each power semiconductor device will typically have its own edge termination. After the substrate is fully formed and processed, the substrate may be diced to separate the individual edge-terminated power semiconductor devices if multiple devices are formed on the same substrate. The power semiconductor devices may have a unit cell structure in which the active region of each power semiconductor device includes a large number of individual unit cells that are disposed in parallel to each other and that together function as a single power semiconductor device.

Power semiconductor devices are designed to block (in the forward or reverse blocking state) or pass (in the forward operating state) large voltages and/or currents. For example, in the blocking state, a power semiconductor device may be designed to sustain hundreds or thousands of volts of electric potential. However, as the applied voltage approaches or passes the voltage level that the device is designed to block, non-trivial levels of current may begin to flow through the power semiconductor device. Such current, which is typically referred to as “leakage current,” may be highly undesirable. Leakage current may begin to flow if the voltage is increased beyond the design voltage blocking capability of the device, which may be a function of, among other things, the doping and thickness of the drift region. However, current leakage can occur for other reasons, such as failure of the edge termination and/or the primary junction of the device. If the voltage on the device is increased past the breakdown voltage to a critical level, the increasing electric field may result in an uncontrollable and undesirable runaway generation of charge carriers within the semiconductor device, leading to a condition known as avalanche breakdown.

A power semiconductor device may also begin to allow non-trivial amounts of leakage current to flow at a voltage level that is lower than the design breakdown voltage of the device. In particular, leakage current may begin to flow at the edges of the active region, where high electric fields may be experienced due to electric field crowding effects. In order to reduce this electric field crowding (and the resulting increased leakage currents), edge termination structures may be provided that surround part or all of the active region of a power semiconductor device. These edge terminations may spread the electric field out over a greater area, thereby reducing the electric field crowding.

In vertical power semiconductor devices, the blocking voltage rating of the device is typically determined by a number of factors, including the thickness and the doping concentration of the drift region. In particular, to increase the breakdown voltage of the device, the doping concentration of the drift region is decreased and/or the thickness of the drift region is increased. Typically, during the design phase, a desired blocking voltage rating is selected, and then the thickness and doping of the drift region are chosen based on the desired blocking voltage rating. Since the drift region is the current path for the device in the forward “on” state, the decreased doping concentration and increased thickness of the drift region may result in a higher on-state resistance for the device. Thus, there is an inherent tradeoff between the on-state resistance and blocking voltage for these devices.

Superjunction-type drift regions have been introduced in which the drift region is divided into alternating, side-by-side heavily-doped n-type and p-type regions. In vertical semiconductor devices, these side-by-side n-type and p-type regions are often referred to as “pillars.” The pillars may have fin shapes, column shapes or other shapes. The thickness and doping of these pillars may be controlled so that the superjunction will act like a p-n junction with low resistance and a high breakdown voltage. Thus, by using superjunction structures, the conventional tradeoff between the breakdown voltage of the device and the doping level of the drift region may be avoided. Typically, at least some of the pillars are formed via ion implantation, and so-called “deep” implantation is used (e.g., ion implantation depths of 2.5 microns to 5 microns or more) to enhance the effect of the superjunction structure. In superjunction devices, the doping concentration in the drift region may be increased in order to reduce the on-state resistance of the device with reduced effect on the breakdown voltage.

FIG. 1 is a schematic cross-sectional diagram of a conventional power semiconductor device in the form of a JBS diode 10 that has a conventional superjunction-type drift region 30. As shown in FIG. 1, the JBS diode 10 includes a cathode contact 20, an ohmic contact layer 22, an n-type substrate 24, the drift region 30 a p-type blocking junction 40, a channel region 46, a Schottky contact 42 and an anode contact 44. The cathode contact 20 and the anode contact 44 may each comprise a highly conductive metal layer. The Schottky contact 42 may comprise a layer that forms a Schottky junction with the drift region 30 and may comprise, for example, an aluminum layer. The n-type substrate 24 may comprise a silicon carbide substrate that is heavily doped with n-type impurities such as nitrogen or phosphorous. The ohmic contact layer 22 may comprise a metal that forms an ohmic contact to n-type silicon carbide so as to form an ohmic contact to the silicon carbide substrate 24. The p-type blocking junction 40 may be a p-type implanted region in an upper portion of the drift region 30 that is heavily implanted with p-type dopants. The channel region 46 is positioned adjacent the p-type blocking junction 40. The channel region 46 is a semiconductor structure that passes current in the on-state and blocks voltage in the blocking state. Current flows through the channel region 46 when the diode 10 is in its forward on-state.

The drift region 30 may comprise a silicon carbide semiconductor region that includes at least one n-type pillar 32 and at least one p-type pillar 34. The n-type pillar 32 and the p-type pillar 34 may each comprise epitaxially grown silicon carbide regions that are doped with n-type and p-type dopants, respectively. The number of charges in the n-type pillar 32 may be approximately equal to the number of charges in the p-type pillar 34. The n-type and p-type pillars 32, 34 may be formed, for example, by implanting ions into predetermined portions of the drift region 30. As known to those skilled in the art, ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer to a certain depth.

Superjunction technology may reduce the specific on-resistance (Rsp) and/or improve power density in high voltage devices. Because the presence of superjunctions reduces the resistance in the drift region of the device, superjunctions are typically more useful for higher voltage devices in which the drift region accounts for a significant portion of the total specific on-resistance of the device.

In a SiC MOSFET device having a blocking voltage of 1200V, the drift region may account for less than 40% of the specific on-resistance, making the use of superjunctions less desirable. However, in a SiC MOSFET device having a blocking voltage of 1700V, the drift region may account for about 60% of the specific on-resistance, making superjunction technology attractive for such devices. However, the drift region of a 1700V MOSFET may be up to 15 microns thick, which may require deep trenching or epitaxial regrowth to form a superjunction structure using currently available technology.

### SUMMARY

A method of forming a semiconductor device according to some embodiments includes providing a semiconductor substrate having a first conductivity type and having an epitaxial structure thereon. The epitaxial structure includes a first region on the substrate, a second region on the first region, and a third region on the second region. The first region, the second region, and the third region have the first conductivity type. The method further includes etching the epitaxial structure to form a mesa stripe and trenches on opposite sides of the mesa stripe. The trenches extend through the third region and the second region to define a respective source region and channel region in the mesa stripe.

The method further includes implanting first dopant ions having a second conductivity type, opposite the first conductivity type, through the trenches and into the first region to form second conductivity type pillars in the first region adjacent a central pillar region in the first region. The second conductivity type pillars and the central pillar region form a superjunction drift region. A source ohmic contact is formed on a top of the mesa stripe, and a drain ohmic contact is formed on the substrate.

In some embodiments, the first dopant ions are implanted along a first crystallographic direction of the epitaxial structure along which implant channeling occurs in the epitaxial structure.

The epitaxial structure may include silicon carbide having a hexagonal crystal structure, and the first crystallographic direction may be a <0001> crystallographic direction. The first dopant ions may implanted at an implant energy of at least about 1.5 MeV.

The first dopant ions may be implanted through bottom surfaces of the trenches and into a portion of the first region beneath the trenches. In particular, the first dopant ions may be implanted into the first region to a depth of at least about 2 microns below bottom surfaces of the trenches.

In some embodiments, the semiconductor substrate is cut at an off-axis angle relative to a direction normal to a growth surface of the semiconductor substrate toward a first direction, and the mesa stripe extends in the first direction. The first direction, the direction normal to the growth surface of the semiconductor substrate, and the <0001> crystallographic direction may all lie in a same plane.

In some embodiments, the second conductivity type pillars include vertical regions in the first region that extend in the direction normal to the growth surface of the semiconductor substrate.

In some embodiments, the etching the epitaxial structure includes forming an etch mask on the third region and anisotropically etching the third region and the second region through the etch mask to form the trenches. The etch mask is used as an implantation mask while implanting the first dopant ions into the first region to obstruct the first dopant ions from entering the mesa stripe.

The epitaxial structure may include a contact region on the third region, and etching the epitaxial structure may include etching the contact region. The contact region may have a higher doping concentration than the third region, and the contact region may obstruct the first dopant ions from penetrating deeper into the mesa stripe.

The semiconductor device may include a plurality of alternating mesa stripes and trenches that extend in a first direction along the semiconductor substrate and have respective opposing first and second ends, and the alternating mesa stripes and trenches may be spaced apart in a second direction that is perpendicular to the first direction.

The mesa stripes may become wider near the first and second ends thereof relative to middle portions of the mesa stripes. The trenches become narrower near the first and second ends thereof relative to middle portions of the trenches.

The third region may include a doped region that defines an active region of the semiconductor device within the doped region and a termination region of the semiconductor device outside the doped region. Widths of the trenches and/or mesa stripes may increase in the second direction towards edges of the semiconductor device within the termination region relative to widths of the trenches and/or mesa stripes within the active region.

The method may further include implanting second dopant ions having the second conductivity type into sidewalls of the channel region to form sidewall gate regions on opposite sidewalls of the channel region.

Implanting the second dopant ions may include implanting the second dopant ions at a tilted angle to form the sidewall gate regions in the channel region and in the second conductivity type pillars.

The first conductivity type may be n-type and the second conductivity type may be p-type.

A method of forming a semiconductor device according to further embodiments includes providing a semiconductor substrate having a first conductivity type and having an epitaxial structure thereon. The epitaxial structure includes a first region on the substrate, a second region on the first region, and a third region on the second region. The first region, the second region, and the third region may have the first conductivity type.

The method further includes etching the epitaxial structure to form a mesa stripe and trenches on opposite sides of the mesa stripe. The trenches may extend through the first region, the second region and the third region.

The method further includes implanting first dopant ions having a second conductivity type, opposite the first conductivity type, into the mesa stripe through sidewalls of the trenches and into the first region to form second conductivity type pillars in the first region adjacent a central pillar region in the first region. The second conductivity type pillars and the central pillar region form a superjunction drift region, and implanting the first dopant ions is performed at a first implant angle relative to a normal direction that is perpendicular to a growth surface of the semiconductor substrate. A source ohmic contact is formed on a top of the mesa stripe, and a drain ohmic contact is formed on the substrate.

The first implant angle may be less than about 20 degrees.

The method may further include implanting second dopant ions having the second conductivity type into upper sidewalls of the mesa stripe to form sidewall gate regions on opposite sidewalls of the second region. Implanting the second dopant ions may be performed at a second implant angle that is greater than the first implant angle. The second implant angle may be greater than about 20 degrees.

In some embodiments, shadowing from adjacent mesa stripes on the semiconductor substrate obstructs the second dopant ions from being implanted into lower portions of the mesa stripe adjacent the first region.

The first conductivity type may be n-type and the second conductivity type may be p-type, and the semiconductor substrate may include silicon carbide.

A semiconductor device according to some embodiments includes a substrate and an epitaxial structure on the substrate. The epitaxial structure includes a drift region, and a mesa stripe on the drift region. The mesa stripe includes a channel region on the drift region, a source region on the channel region, and sidewall gate regions on opposite sides of the channel region. The channel region and the source region have a first conductivity type and the sidewall gate regions have a second conductivity type opposite the first conductivity type. The drift region includes a central pillar having the first conductivity type and outer pillars on opposite sides of the central pillar. The outer pillars have the second conductivity type, and the outer pillars and the central pillar form a superjunction structure in the drift region.

The drift region may further include a first region beneath the central pillar and the outer pillars, the first region having the first conductivity type.

The central pillar and the outer pillars may have a height of at least about 2 microns.

The epitaxial structure may include a pair of trenches on opposite sides of the mesa, wherein the outer pillars are provided beneath respective ones of the trenches.

The sidewall gate regions may extend beneath respective ones of the trenches.

The semiconductor device may include a plurality of alternating mesa stripes and trenches that extend in a first direction along the semiconductor substrate and have respective opposing first and second ends, and the alternating mesa stripes and trenches may be spaced apart in a second direction that is perpendicular to the first direction.

The mesa stripes may become wider near the first and second ends thereof relative to middle portions of the mesa stripes. The trenches become narrower near the first and second ends thereof relative to middle portions of the trenches.

The third region may include a doped region that defines an active region of the semiconductor device within the doped region and a termination region of the semiconductor device outside the doped region. Widths of the trenches and/or mesa stripes may increase in the second direction towards edges of the semiconductor device within the termination region relative to widths of the trenches and/or mesa stripes within the active region.

The substrate may include silicon carbide having a hexagonal polytype and having an off-cut angle towards a first direction relative to a crystallographic direction of the substrate along which implant channeling occurs, wherein the mesa stripe extends in the first direction. The crystallographic direction may be a <0001> crystallographic direction.

A semiconductor device according to further embodiments includes a substrate, and a mesa on the substrate. The mesa includes a drift region, a channel region on the drift region, and a source region on the channel region. The channel region and the source region have a first conductivity type.

The drift region includes a central pillar having the first conductivity type and outer pillars on opposite sides of the central pillar, and the outer pillars have a second conductivity type opposite the first conductivity type. The outer pillars and the central pillar form a superjunction structure in the drift region.

The mesa may further include sidewall gate regions on opposite sides of the channel region, the sidewall gate regions having the second conductivity type.

The drift region may further include a first region beneath the central pillar and the outer pillars, the first region having the first conductivity type. The central pillar and the outer pillars may have a height of at least about 2 microns.

### BRIEF DESCRIPTION OF THE DRAWINGS

FIG. 1 is a schematic cross-sectional diagram of a conventional power semiconductor device that has a superjunction-type drift region.

FIG. 2 is a schematic diagram illustrating the relative locations of various crystallographic axes in 4H silicon carbide.

FIGS. 3A-3C illustrate the lattice structure of 4H silicon carbide as viewed along the <0001>, <11-23> and <11-20> crystallographic axes, respectively.

FIG. 4 illustrates a cell of a SiC JFET structure according to some embodiments.

FIG. 5 illustrates simulated high-energy channeled implantation of Al ions into SiC along the <0001> axis at various implant energy levels and implant doses.

FIGS. 6A and 6B illustrate the use of channeled implants to form the p-type pillars of a superjunction.

FIGS. 7A to 7F illustrate operations for forming a SiC JFET structure according to some embodiments.

FIGS. 8A and 8B illustrate a layout of a SiC JFET structure according to some embodiments.

FIG. 9 illustrates a cell of a SiC JFET structure according to further embodiments.

FIGS. 10A to 10E illustrate operations for forming a SiC JFET structure according to further embodiments.

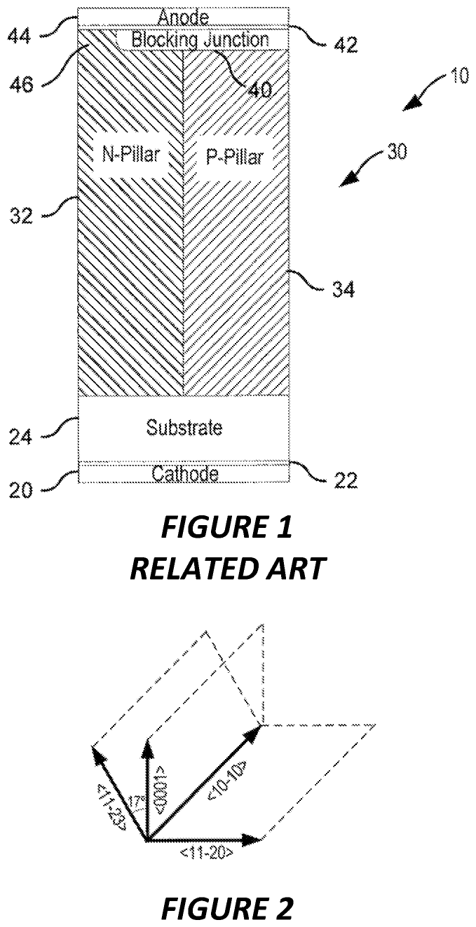

### DETAILED DESCRIPTION OF EMBODIMENTS

Power semiconductor devices having superjunction-type drift regions have conventionally been formed in two different ways. Under the first approach, a semiconductor drift region having a first conductivity type (e.g., n-type) may be epitaxially grown on a substrate, and then an etching step may be performed to form one or more trenches in the epitaxial layer to create one or more pillars of semiconductor material having the first conductivity type. The sidewall(s) of the trench(s) may then be oxidized, and the trench(es) may then be refilled by epitaxially growing semiconductor material that is doped with impurities having a second conductivity type (e.g., p-type) to form one or more pillars of semiconductor material having the second conductivity type.

In the second approach for forming superjunction-type drift regions, the semiconductor drift region may be epitaxially grown on the substrate and then n-type and p-type dopants may be selectively implanted into the drift region to form the respective n-type and p-type pillars. The implanted dopants may be diffused throughout the pillars via, for example, thermal annealing. If necessary, multiple epitaxial growth and ion implantation steps may be performed to form a superjunction-type drift region having a desired thickness. Either approach may be used to form superjunction-type drift regions in, for example, silicon power devices. As will be apparent from the discussion that follows, the semiconductor pillars that are used to form superjunction-type drift regions are regions which extend vertically through at least a portion of the drift region and that can have a variety of different shapes.

The above-described conventional techniques for forming superjunction-type drift regions may not be very well-suited for forming superjunction-type drift regions in certain higher bandgap semiconductor materials, such as silicon carbide. For example, the first conventional fabrication method that is discussed above, namely, forming a trench in the drift region that is refilled with semiconductor material of the second conductivity type, may be problematic in silicon carbide because the breakdown voltage of the oxide layer that is formed between the n-type and p-type pillars is about the same as the breakdown voltage for silicon carbide. As a result, during reverse bias operation, carrier tunneling into the oxide layer may occur that can result in leakage currents through the oxide or even destructive avalanche breakdown. Additionally, in silicon carbide, non-uniform incorporation of the second conductivity type dopants may occur in the vicinity of the trench sidewalls during the epitaxial trench refill step, which may make it difficult to control the charge of the second conductivity type pillar.

The second of the above-described conventional techniques may not work well in silicon carbide, because n-type and p-type dopants do not tend to diffuse well in silicon carbide, even at high temperatures. This is also true in various other compound semiconductor materials such as gallium nitride based semiconductor materials, which dissociate before thermal diffusion can occur. As a result, the ion implantation process provides the primary means of obtaining a desired dopant profile in the drift region. When dopant ions are implanted into a semiconductor layer, the ions damage the crystal lattice of the semiconductor layer, which typically can only partly be repaired by thermal annealing. The depth at which the ions are implanted is directly related to the energy of the implant, i.e., ions implanted into a semiconductor layer at higher energies tend to go deeper into the layer. Thus, forming deep implanted regions requires high energy implants. However, lattice damage is also directly related to implant energy, as higher energy implants also tend to cause more lattice damage than lower energy implants, and the uniformity of the ion implant decreases with increasing implant depth. Thus, to form implanted regions that have good doping uniformity by depth and/or acceptable levels of lattice damage, it is necessary to perform a large number of successive epitaxial growth/ion implantation steps to obtain drift layers having sufficient thicknesses to achieve breakdown voltages on the order of several kilovolts. Such large numbers of epitaxial growth and ion implantation steps increase the time and cost of device fabrication.

FIG. 2 is a schematic diagram illustrating the relative locations of various crystallographic axes in 4H silicon carbide. As shown in FIG. 2, the <10-10> crystallographic axis is perpendicular to each of the <0001>, <11-20> and <11-23> crystallographic axes. The <11-20> crystallographic axis is perpendicular to the <0001> crystallographic axis, and the <11-23> crystallographic axis is offset by about 17° from the <0001> crystallographic axis in the direction away from the <11-20> crystallographic axis.

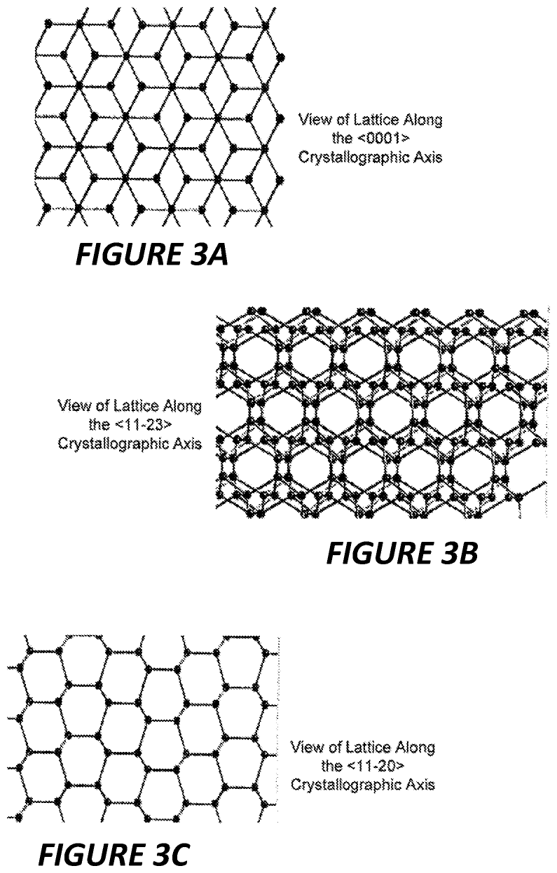

FIGS. 3A-3C illustrate the lattice structure of 4H silicon carbide as seen along the <0001>, <11-23> and <11-20> crystallographic axes, respectively. As shown in FIG. 3A, the density of atoms at the surface (the atoms are shown by the small circles in FIG. 3A) is relatively low, which is a favorable condition for deeper ion implant depths. A plurality of channels are provided between the atoms which allow for channeling of the implanted ions to relatively deeper depths into the semiconductor material. However, the channels themselves are relatively small in cross-sectional area. Relatively speaking, the smaller a channel is in cross-sectional area, the shallower the implant depth. Thus, while ion implantation along the <0001> crystallographic axis will exhibit channeling, the implant depths achievable may be limited.

FIG. 3B illustrates the lattice structure of 4H silicon carbide as viewed along the <11-23> crystallographic axis. The lattice structure will look the same as shown in FIG. 3B when viewed along any of the <−1-123>, <1-213>, <−12-13>, <Feb. 1, 2013> and <−2113> crystallographic axes. Given the hexagonal lattice of 4H silicon carbide, the six crystallographic axes listed above are all offset by 17 degrees from the <0001> crystallographic axis and are spaced apart from each other by 60 degree increments. The vectors that are offset by 17 degrees from the <0001> crystallographic axis form a cone that rotates through 360 degrees. The <11-23>, <−1-123>, <1-213>, <−12-13>, <Feb. 1, 2013> and <−2113> crystallographic axes all extend along this cone, and are separated from each other by 60 degrees. At most rotation angles about this cone, the lattice structure will appear “crowded” with closely-spaced atoms throughout. However, as shown with reference to FIG. 3B, at six different locations that correspond to the <11-23>, <−1-123>, <1-213>, <−12-13>, <Feb. 1, 2013> and <−2113> crystallographic axes, the atoms “line up” so that distinct channels appear in the lattice structure. As can be seen in FIG. 3B, along these six crystallographic axes, the density of atoms at the surface is increased as compared to the example of FIG. 3A, which will typically result in increased scattering of ions. Advantageously, however, the channels that are provided between the atoms have a larger cross-sectional area as compared to the channels in the example of FIG. 3A. This may allow for increased implant depths.

As can be seen in FIG. 3C, when 4H silicon carbide is viewed along the <11-20> crystallographic axis, the density of atoms at the surface may be very low, and channels having large cross-sectional areas are provided within the lattice structure. Such a structure may allow for very deep implant depths. Unfortunately, however, the <11-20> crystallographic axis is typically nearly perpendicular to the major faces of a silicon carbide wafer when the wafer is cut in a traditional manner, and hence it may be difficult to provide silicon carbide wafers that have a major face cut along, or at a relatively small tilt from, the <11-20> crystallographic axis. Thus, ion implantation along the <11-20> crystallographic axis may not be an option in many applications.

Junction field effect transistor (JFET) devices have significantly lower specific on-resistance than MOSFETs, primarily because they lack a surface channel region. Superjunction technology can help reduce the specific on-resistance of JFET devices having a blocking voltage rating of 1200V, because at 1200V, about 60% of total specific on-resistance of the JFET is in the drift region. Moreover, a 1200V JFET has a drift region that is about 10 microns thick, which means that a large part the drift region can be converted to a charge-balanced superjunction region with a single implant and no epitaxial regrowth required. Embodiments described herein provide methods that are suitable for forming a SiC JFET device having a superjunction region in the drift layer.

Some embodiments described herein provide SiC JFET devices that have reduced specific on-resistance, and methods of forming such JFET devices in SiC.

Some embodiments provide methods of forming a SiC superjunction device that can reduce the specific on-resistance of a power device. In particular, some embodiments employ a high energy channeled Al implant along the <0001> crystallographic direction to form a superjunction in a SiC JFET device. The SiC JFET device may have a mesa structure. Some embodiments use a highly doped mesa implant as a de-channeling screen to restrict the superjunction implant to only a trenched region adjacent the mesa, and to self-align the superjunction implant to the mesa and trenches

Some embodiments use trenches in a termination region of the device to self-align the superjunction implant in such a way that charge balance can be broken as desired in the termination area to achieve high blocking voltages.

In an alternate embodiment, implants with different tilts may be used to form superjunctions and channel implants in a JFET mesa.

In some embodiments, trench and mesa fingers of a SiC JFET device may be laid out along the direction of the miscut of a SiC wafer relative to the <0001> crystallographic direction from the wafer normal such that within the active cell there is no effect of the miscut on charge balance in the superjunction region.

These and other example embodiments will now be described with reference to the attached drawings. It will be appreciated that features of the different embodiments disclosed herein may be combined in any way to provide many additional embodiments.

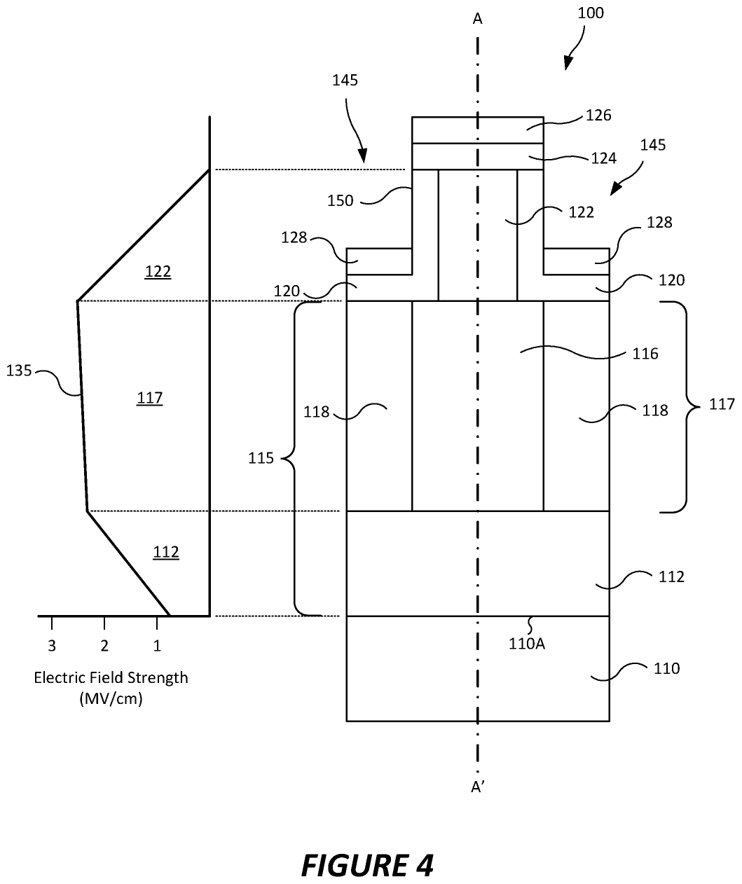

FIG. 4 illustrates a cell of a SiC JFET structure 100 according to some embodiments. The SiC JFET structure 100, or SiC JFET 100, may have a mesa configuration including a central mesa 150 that extends in a direction into the plane of FIG. 4 to form a mesa stripe or finger (referred to herein as a mesa stripe 150). Trenches 145 are formed on opposite sides of the mesa stripe 150, and also extend in the direction of the mesa stripe 150. The mesa/trench structure shown in FIG. 4 may be a single cell of a device that has multiple such cells arranged in parallel with a termination region surrounding the cells.

The SiC JFET 100 includes a SiC substrate 110, which may have a 2H, 4H or 6H polytype. As discussed below, the SiC substrate may have an off-axis structure, such that the growth surface 110A of the substrate on which the SiC JFET 100 is formed is tilted by an off-axis angle of about 3° to 5° away from the <0001> crystallographic direction to promote epitaxial growth thereon. The SiC substrate 110 may include n+ SiC having a net n-type doping concentration greater than about 1E17 cm-3. A drain contact (not shown) is formed to the SiC substrate 110.

An epitaxial layer structure is formed on the substrate via epitaxial crystal growth. The epitaxial layer structure is processed using semiconductor processing techniques, such as ion implantation, etching, annealing, etc., to form one or more layers or regions of the SiC JFET 100 as described below.

The SiC JFET 100 includes a drift region 115 on the substrate 110. The drift region 115 includes a so-called “one-dimensional” (1-D) region 112 on the substrate 110 and a superjunction region 117 on the 1-D region 112. The 1-D region 112 may include n-type SiC having a net n-type doping concentration of about 8E15 cm⁻³ to 8E16 cm⁻³, in some embodiments about 3E16 cm-3 to 5E16 cm-3, and in some embodiments about 4E16 cm-3, and may have a thickness of about 3 microns to 4 microns, and in some embodiments about 3.5 microns.

The superjunction region 117 includes an n-type central pillar 116 and p-type pillars 118 on opposing sides of the central pillar 116. The n-type central pillar 116 and p-type pillars 118 may have a thickness (i.e., a height in the vertical direction as shown in FIG. 4) of about 3.5 microns to 4.5 microns, and in some embodiments about 4 microns, for a total thickness of the drift region 115 of about 6 microns to 8 microns, and in some embodiments about 7.5 microns. The n-type central pillar 116 may have a net doping concentration of n-type dopants of about 5E16 cm⁻³ to 5E17 cm⁻³, and in some embodiments about 2E17 cm⁻³, and the p-type pillars 118 may have a net doping concentration of p-type dopants of about 5E16 cm3 to 5E17 cm⁻³, and in some embodiments about 2E17 cm3. The central pillar 116 and the p-type pillars 118 are vertical relative to the growth surface 110A of the substrate 110. That is, the central pillar 116 and the p-type pillars 118 extend in a vertical direction that is normal to the growth surface 110A of the substrate 110 and are not substantially tilted relative to the vertical direction.

The p-type pillars 118 may be formed using high-energy vertical channeled implants along the <0001> crystallographic direction. As discussed further below, the channeled implants to form the p-type pillars 118 may be performed after implanting the n+ source region 124 and n++ contact region 126 and forming the trenches 145, but before implantation of the p-type sidewall gate regions 120 and p+ gate contact regions 128. The highly doped n+ source region 124 may act as an additional implant mask (in addition to the oxide mask used to form the trenches 145). An implant energy greater than 1 MeV, and in some cases up to about 2.5 MeV, may be used to form the p-type pillars 118. The p+ gate contact regions 128 are formed by ion implantation after the p-type pillars 118 are formed.

As further discussed below, the implant may be performed by tilting the wafer by an angle equal to the off-axis angle of the substrate 110 in a direction aligned with the direction of the mesa fingers 150, so that the p-type pillars 118 are vertical relative to the central pillar 116 to preserve charge balance in the superjunction region 117.

The dimensions and doping concentrations of the n-type central pillar 116 and p-type pillars 118 may be selected such that the superjunction region 117 is approximately charge-balanced. That is, the total n-type charge and p-type charge in the superjunction region 117 should be approximately equal, although there may be a slight charge imbalance in the superjunction region 117 with slightly higher n-type charge. For example a charge imbalance of up to about 20% in the superjunction region 117 may be tolerable.

The JFET structure 100 shown in FIG. 4 may have a breakdown voltage of about 1440 V, about 1000 V of which is in the superjunction region 117. It will be appreciated that other thicknesses (heights), widths and/or doping concentrations of the n-type central pillar 116 and p-type pillars 118 may be selected depending on the desired blocking voltage level of the device.

An n-type channel region 122 is formed on the superjunction region 117, and extends into the mesa stripe 150. P-type sidewall gate regions 120 are provided on the superjunction region 117 adjacent the n-type channel region 122. The sidewall gate regions 120 extend into and up the mesa stripe 150 adjacent the channel region 122. Heavily doped p+ gate contact regions 128 are formed on the sidewall gate regions 120 to facilitate the formation of gate ohmic contacts to the SiC JFET device 100.

An n+ source layer 124 is formed on the channel region 122 and the sidewall gate regions 120, and an n++ contact layer 126 is formed on the n+ source layer 124. The total thickness of the n+ source layer 124 and the n++ contact layer 126 may be about 1 micron, and the n+ source layer 124 may be spaced apart from the p+ gate contact regions 128 by a distance of about 1 micron. The mesa stripe 150 may have a width of about 1.2 microns.

FIG. 4 also shows a conceptual graph 135 of simulated electric field strength (referenced to the drain) in the drift region 115 and the channel region 122 along a line A-A′ in the center of the device when the device is in a reverse blocking condition. As shown in FIG. 4, starting at the top of the channel region 122, the drain electric field rises from zero to a maximum value at the interface between the channel region 122 and the drift region 115. Within the superjunction region 117, the electric field strength in the structure of FIG. 4 may be about 2.5 MV/cm, although a slight charge imbalance in the superjunction region 117 may cause the electric field strength to vary along the length of the superjunction region 117. Within the 1D region 112, the electric field falls linearly.

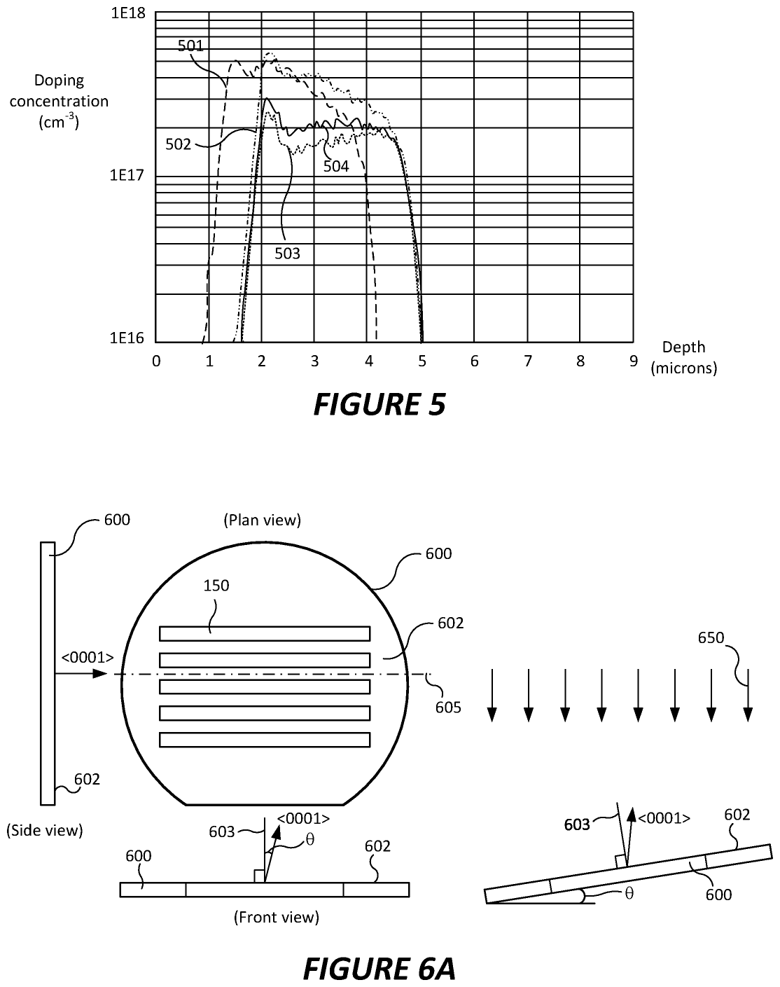

FIG. 5 illustrates simulated high-energy channeled implantation of Al ions into SiC along the <0001> axis at various implant energy levels and implant doses. In particular, Curve 501 represents a simulated implant of Al at an implant energy of 1.5 MeV and a dose of 1E14 cm-2. Curve 502 represents a simulated implant of Al at an implant energy of 2.5 MeV and a dose of 1E14 cm-2. Curve 503 represents a simulated implant of Al at an implant energy of 2.5 MeV and a dose of 5E13 cm-2, and curve 504 represents a simulated implant of Al at an implant energy of 2.5 MeV and a dose of 6E13 cm-2.

As shown in FIG. 5, implants at an implant energy of 2.5 MeV should form deeper p-type regions than implants at 1.5 MeV, and implants at higher doses should form p-type regions with greater dopant concentrations. An implantation at an energy of 2.5 MeV and a dose of 6E13 cm-2 appears to provide a nearly flat concentration of dopants at a concentration of about 2E17 cm⁻³ over a depth of 2 microns to 5 microns. Shallow (i.e., lower energy) implant steps can be used to fill in the region at a depth of 0 to 2 microns.

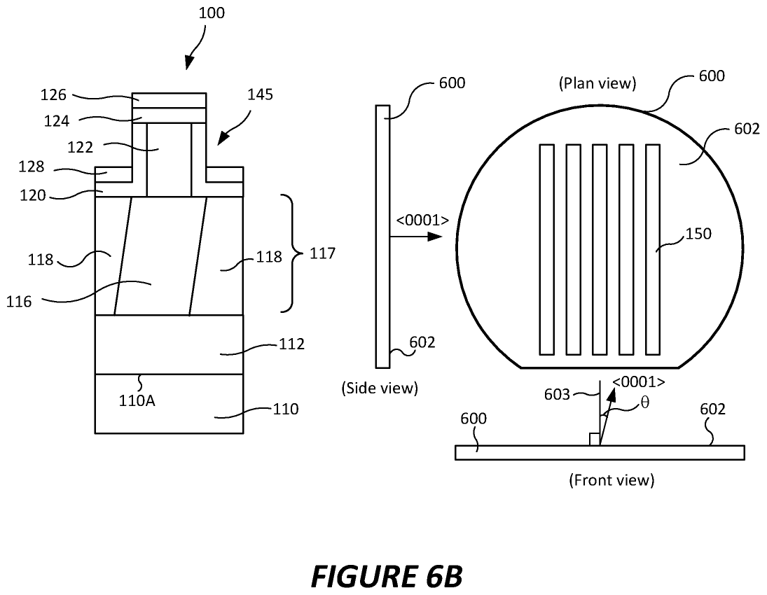

FIG. 6A illustrates the use of channeled implants to form the p-type pillars 118. In particular, the left side of FIG. 6A shows plan, side and front views of a 4H-SiC wafer 600 that is cut at an off-axis angle θ relative to the <0001> crystallographic direction, so that the <0001> crystallographic direction is tilted away from the direction 603 that is normal to the growth surface 602 of the wafer 600 by the off-axis angle θ. In particular, the off-axis angle may be tilted toward a crystallographic direction that is perpendicular to the <0001> crystallographic direction, such as the <11-20> or <10-10> crystallographic directions. The off-axis angle θ may be about 3° to 5°. In the example shown in FIG. 6A, the wafer 600 is cut at an off-axis angle θ relative to the <0001> crystallographic direction that is tilted toward the horizontal direction.

A plurality of mesa stripes 150 are formed on the growth surface 602 of the wafer 600. As noted above, the mesa stripes 150 are arranged as mesa stripes or mesa fingers on the surface 602 of the wafer 600. The mesa stripes 150 extend in the same direction by which the crystal structure of the wafer is tilted toward the <0001> crystallographic direction, i.e., the horizontal direction in FIG. 6A. Thus, the mesa stripes 150, the direction 603 that is normal to the wafer surface 602, and the <0001> crystallographic direction of the wafer 600 all lie in the same plane 605.

As shown in the right side of FIG. 6A, when ions 650 are implanted into the wafer 600, the wafer 600 is tilted by the same off-axis angle θ, so that the ions 650 are implanted into the wafer 600 along the <0001> crystallographic direction of the wafer crystal. Because the mesa stripes 150 extend in the same direction as the wafer 600 is tilted, the mesa stripes 150 may not shadow the implanted ions on either side of the mesa stripes 150.

For comparison, FIG. 6B illustrates the use of channeled implants to form the p-type pillars 118 when the mesa stripes 150 are arranged to extend in a direction that is not parallel to the direction of the tilt of the wafer 600. In particular, in FIG. 6B, the mesa stripes extend in a direction that is perpendicular to the direction of the tilt of the wafer 600. In that case, the implants along the <0001> direction used to form the p-type pillars 118 are shadowed by the mesa stripe 150, and the interfaces between the central pillar 116 and the p-type pillars 118 are angled or tilted relative to the vertical direction, which may interfere with charge balance in the superjunction region 117.

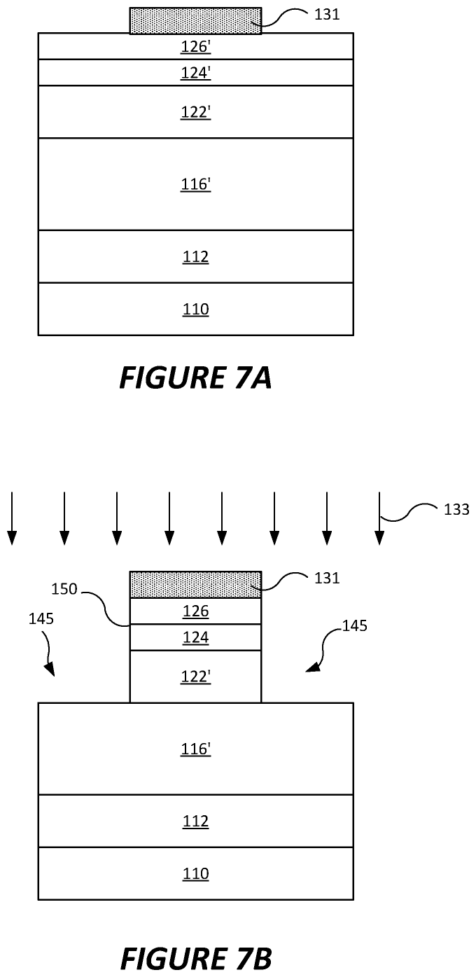

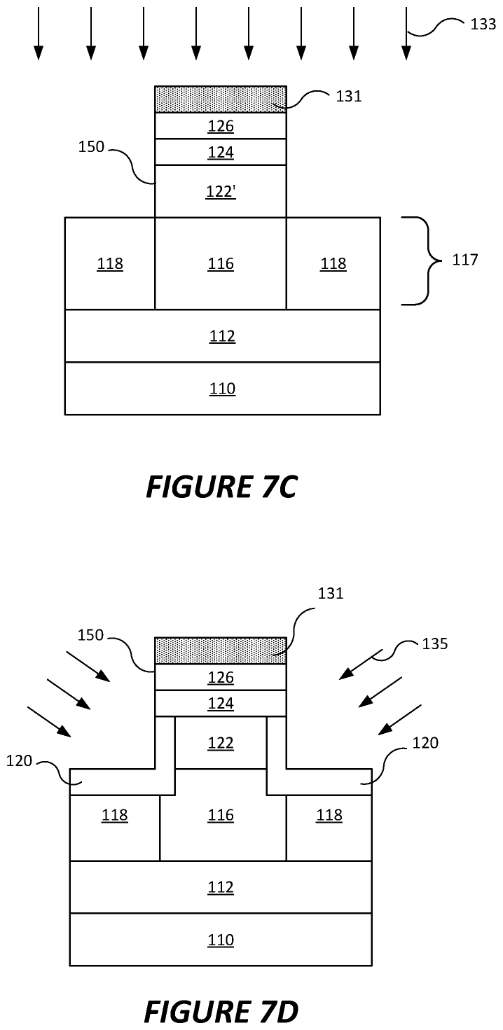

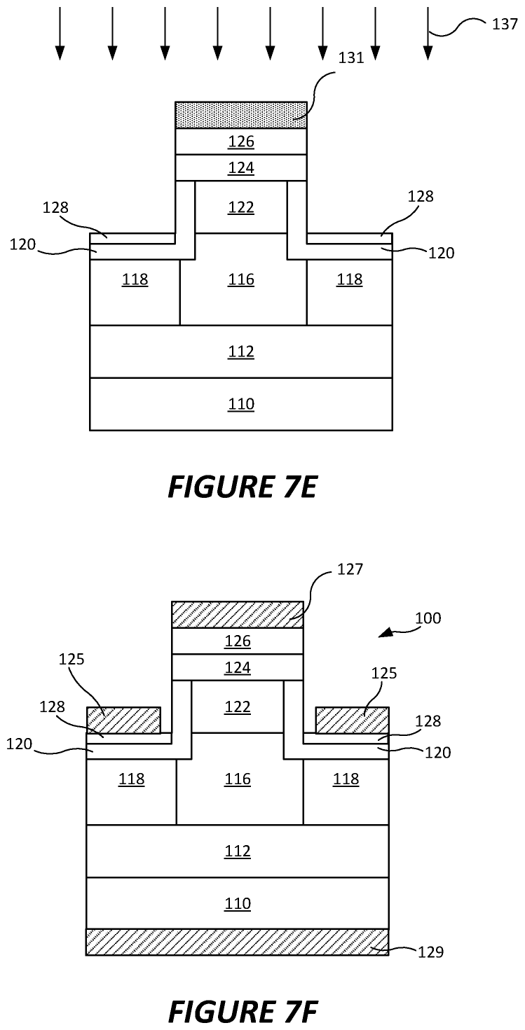

FIGS. 7A to 7F illustrate operations for forming a SiC JFET structure 100 according to some embodiments. Referring to FIG. 7A, a 4H-SiC substrate 110 is provided. The substrate 110 may be cut at an off-axis angle of about 3° to 5° away from the <0001> crystallographic direction.

An epitaxial layer structure is formed on the substrate 110, including an n-type 1-D region 112 and an n-type precursor layer 116′ that will form the drift region of the device. An n-type channel precursor layer 122′ is formed on the precursor layer 116′. An n+ source precursor layer 124′ and n++ contact precursor layer 126′ are formed on the channel precursor layer 122′. The n+ source precursor layer 124′ and n++ contact precursor layer 126′ may be formed, for example, by implantation of n-type dopants into the channel precursor layer 122′ using conventional methods.

The n-type 1-D region 112 may have a thickness of about 3 microns to 4 microns, and in some embodiments about 3.5 microns and a net doping concentration of about 8E15 cm-3 to 8E16 cm⁻³, in some embodiments about 3E16 cm-3 to 5E16 cm⁻³, and in some embodiments about 4E16 cm⁻³. The n-type precursor layer 116′ may have a thickness of about 3.5 microns to 4.5 microns, and in some embodiments about 4 microns, and a net doping concentration of about 5E16 cm⁻³ to 5E17 cm⁻³, and in some embodiments about 2E17 cm⁻³. The n-type channel precursor layer 122′ may have a thickness of about 2 microns and a net doping concentration of about 1E17 cm⁻³. The n+ source precursor layer 124′ may have a thickness of about 0.5 microns and a net doping concentration of about 1E18 cm⁻³. The n++ contact precursor layer 126′ may have a thickness of about 0.5 microns and a net doping concentration of greater than about 1E19 cm⁻³. Together, the n+ source precursor layer 124′ and the n++ contact precursor layer 126′ may have a thickness of about 1 micron.

Referring to FIG. 7B, a mask 131 is formed on the n++ contact precursor layer 126′, and the n+ source precursor layer 124′, n++ contact precursor layer 126′ and channel precursor layer 122′ are anisotropically etched 133 using conventional methods, such as reactive ion etching or inductively coupled plasma etching, to define a mesa stripe 150 and trenches 145 adjacent the mesa stripe 150. Etching the structure to form the mesa stripe 150 defines an n+ source region 124 and an n++ contact region 126 in the mesa stripe 150. The mesa stripe 150 may have a width of about 1.2 microns.

Referring to FIG. 7C, leaving the mask 131 in place, p-type dopant ions 133 are implanted into the structure to form p-type pillars 118 in the n-type precursor layer 116′. The dopant ions 133 are implanted using high-energy (e.g., greater than about 1.5 MeV) channeled implants along the <0001> crystallographic direction to a depth of at least about 2 microns, and up to about 4 microns. Additional shallow (lower energy) implants may be performed to fill in the portion of the p-type pillars 118 at a depth from 0 to about 2 microns as needed. The implanted ions 133 are shielded from entering the mesa stripe 150 by the implant mask 131 and the n++ contact region 126 in the mesa stripe 150. In particular, the n++ contact region 126 in the mesa stripe 150 is so highly doped that the n-type dopants in the n++ contact region 126 may cause the dopant ions 133 to become de-channeled, thereby obstructing the dopant ions 133 from penetrating deeper into the mesa stripe 150. This step defines the superjunction region 117 of the device including the central pillar 116 between the p-type pillars 118. Implanted dopant ions may be activated using an implant activation anneal, as known in the art.

Referring to FIG. 7D, p-type sidewall gate regions 120 are formed in the sides of the mesa stripe 150 and upper portions of the p-type pillars 118 by angled implantation of p-type dopants 135 into the structure. This step defines the channel region 122 between the p-type sidewall gate regions 120. In addition to being performed at a tilted angle relative to the wafer normal, the implantation of the p-type dopant ions 135 to form the sidewall gate regions 120 is performed at different twist or azimuthal angles, so that both opposing sidewalls and the ends of the mesa stripes 150 are implanted. This may be done using implantations at 0, 90, 180 and 270 degree twist angles.

Referring to FIG. 7E, p-type dopant ions 137 are implanted into the structure to form p+ gate contact regions 128 in the p-type sidewall gate regions 120 above the p-type pillars 118.

Referring to FIG. 7F, the mask 131 is removed. A source contact 127 is formed on the n++ source contact region 126, gate contacts 125 are formed on the p+ gate contact regions 128, and a drain contact 129 is formed on the backside of the substrate 110 to complete the JFET device structure 100.

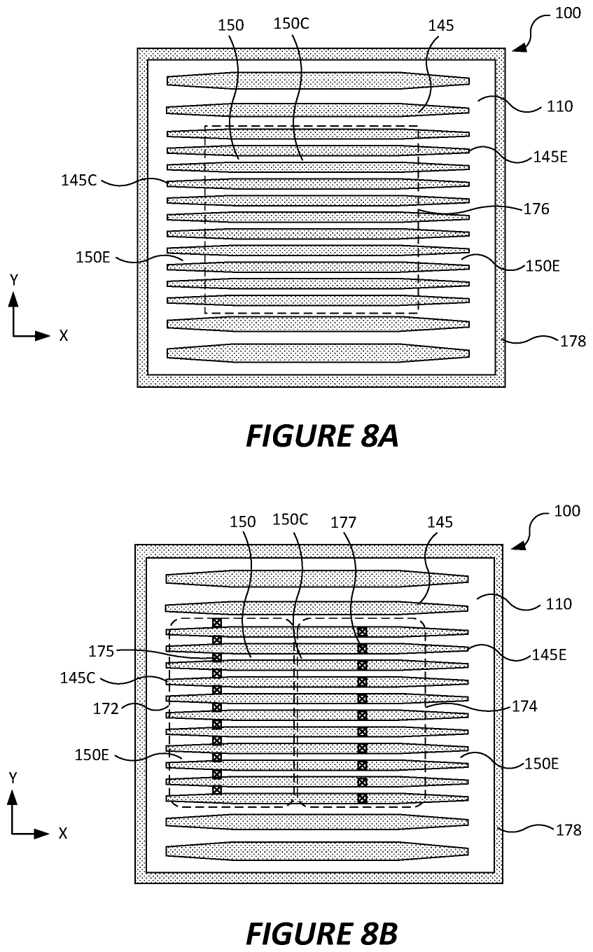

FIGS. 8A and 8B illustrate a layout of some features of a JFET device 100 according to some embodiments. The layout shown in FIGS. 8A and 8B is a plan view of a JFET device 100 having a plurality of alternating mesa stripes 150 and trenches 145 beneath which p-type regions including the p-type pillars 118 are formed as shown in FIG. 7F. FIG. 8A illustrates implanted areas of the mesa stripes 150 and trenches 145 of the JFET device 100, and FIG. 8B illustrates metallization patterns of the JFET device 100.

Referring to FIGS. 7F, 8A and 8B, the mesa stripes 150 and trenches 145 are arranged to extend in a first direction (the X-direction) on the substrate 110, and are arranged in an alternating fashion in a second direction (the Y-direction) along the substrate 110.

The JFET device 100 includes an n+ implanted area 176 that forms the n+ source regions 124 and n++ contact regions 126. The active region of the JFET device 100 generally corresponds to the area of the device within the n+ implanted area 176, and the termination region of the JFET device 100 is generally the area outside the active region. A p-implanted trench 178 surrounds the JFET device 100. As shown in FIG. 8A, the trenches 145 and the implanted regions 118, 120, 128

beneath the trenches 145 have end portions 145E at opposite ends thereof. The trenches 145 and the implanted regions 118, 120, 128 beneath the trenches 145 are tapered towards the end portions 145E in the first direction such that they contain less p-type charge near the ends 150E of the mesa stripes 150 in the termination region. Stated differently, The mesa stripes 150 extend in a first direction (X-direction) along the device and have opposing first and second ends 150E. The width of the mesa stripes 150 increase in the first direction from a middle portion 150C of the mesa stripe 150 within the active region of the JFET device 100 towards the first and second ends 150E outside the active region of the JFET device 100. This provides an edge termination near the lateral edges of the JFET device 100 for the orientation shown in FIGS. 8A and 8B.

Likewise, the mesa stripes 150 and the trenches 145 gradually become wider in the Y-direction outside the active region of the device such that the trenches 145 are both wider and spaced farther and farther apart in the Y-direction from the central portion of the JFET device 100 toward the upper and lower edges of the JFET device 100. This provides an edge termination near the upper and lower edges of the JFET device 100 for the orientation shown in FIGS. 8A and 8B.

Referring to FIG. 8B, the JFET device 100 includes a source pad 172 which contacts the source contacts 127 on the tops of the mesa stripes 150 through a plurality of source vias 175. The JFET device 100 further includes a gate pad 174 which contacts the gate contacts 125 on the bottoms of the trenches 145 through a plurality of gate vias 177.

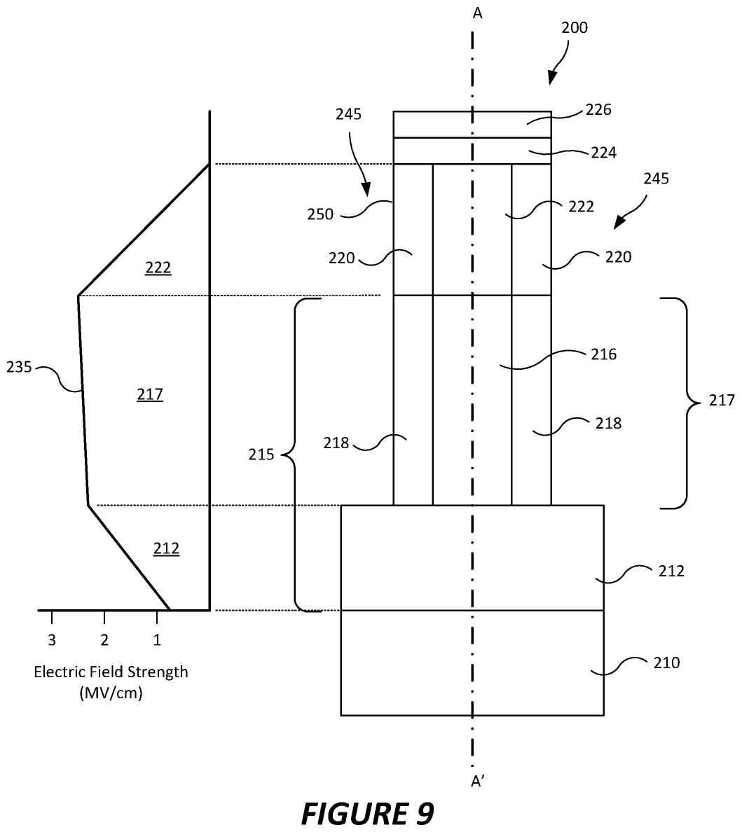

FIG. 9 illustrates a cell of a SiC JFET structure 200 according to further embodiments. The SiC JFET structure 200, or SiC JFET 200, may have a mesa configuration including a mesa stripe 250 that extends in a direction into the plane of FIG. 9. Trenches 245 are formed on opposite sides of the mesa stripe 250, and also extend in the direction of the mesa stripe 250. The mesa/trench structure shown in FIG. 9 may be a single cell of a device that has multiple such cells arranged in parallel.

The SiC JFET 200 includes a SiC substrate 210, which may have a 2H, 4H or 6H polytype. The SiC substrate 210 may have an off-axis structure, such that the surface of the substrate on which the SiC JFET 200 is formed is tilted by an off-axis angle of about 3° to 5° away from the <0001> crystallographic direction to promote epitaxial growth. The SiC substrate 210 may include n+ SiC having a net n-type doping concentration greater than about 1E17 cm⁻³. A drain contact (not shown) is formed to the SiC substrate 210.

The SiC JFET 200 includes a drift region 215 on the substrate 210. The drift region 215 includes a 1-D region 212 on the substrate 210 and a superjunction region 217 on the 1-D region 212. The 1-D region 212 may include n-type SiC having a net n-type doping concentration of about 1E16 cm-3 to 1E17 cm3, and in some embodiments about 4E16 cm3, and may have a thickness of about 3 microns to 4 microns, and in some embodiments about 3.5 microns.

The superjunction region 217 includes an n-type central pillar 216 and p-type pillars 218 on opposing sides of the central pillar 216. The n-type central pillar 216 and p-type pillars 218 may have a thickness (i.e., a height in the vertical direction as shown in FIG. 9) of about 3.5 microns to 4.5 microns, and in some embodiments about 4 microns, for a total thickness of the drift region 215 of about 7.5 microns. The n-type central pillar 216 may have a net doping concentration of n-type dopants of about 5E16 cm3 to 5E17 cm⁻³, and in some embodiments about 2E17 cm⁻³, and the p-type pillars 218 may have a net doping concentration of p-type dopants of about 5E16 cm⁻³ to 5E17 cm⁻³, and in some embodiments about 2E17 cm⁻³.

The p-type pillars 218 may be formed using low-angle implants (relative to the normal direction). P+ sidewall gate regions 220 are formed by angled implantation at a higher angle (relative to normal) after the p-type pillars 218 are formed.

The dimensions and doping concentrations of the n-type central pillar 216 and p-type pillars 218 may be selected such that the superjunction region 217 is approximately charge-balanced. That is, the total n-type charge and p-type charge in the superjunction region 217 should be approximately equal, although there may be a slight charge imbalance in the superjunction region 217 with slightly higher n-type charge. For example a charge imbalance of up to about 20% in the superjunction region 217 may be tolerable.

The JFET structure 200 shown in FIG. 9 may have a breakdown voltage of about 1440 V, about 1000 V of which is in the superjunction region 217. It will be appreciated that other thicknesses, widths and/or doping concentrations of the n-type central pillar 216 and p-type pillars 218 may be selected depending on the desired blocking voltage level of the device.

An n-type channel region 222 is formed on the superjunction region 217, and extends into the mesa stripe 250. P-type sidewall gate regions 220 are provided on the superjunction region 217 adjacent the n-type channel region 222. The sidewall gate regions 220 extend into the mesa stripe 250 adjacent the channel region 222. Gate contact regions (not shown) are formed on the sidewall gate regions 220 outside the plane of FIG. 9 to facilitate the formation of gate ohmic contacts to the SiC JFET device 200.

An n+ source layer 224 is formed on the channel region 222 and the sidewall gate regions 220, and an n++ contact layer 226 is formed on the n+ source layer 224. The total thickness of the n+ source layer 224 and the n++ contact layer 226 may be about 1 micron, and the n+ source layer 224 may be spaced apart from the p+ gate contact regions 128 by a distance of about 1 micron. The mesa stripe 250 may have a width of about 1.2 microns.

FIG. 9 also shows a conceptual graph 235 of simulated electric field strength (referenced to the drain) in the drift region 215 and the channel region 222 along a line A-A′ in the center of the device when the device is in a reverse blocking condition. As shown in FIG. 9, starting at the top of the channel region 222, the drain electric field rises from zero to a maximum value at the interface between the channel region 222 and the drift region 215. Within the superjunction region 217, the electric field strength in the structure of FIG. 9 may be about 2.5 MV/cm, although a slight charge imbalance in the superjunction region 217 may cause the electric field strength to vary along the length of the superjunction region 217. Within the first region 212, the electric field falls linearly.

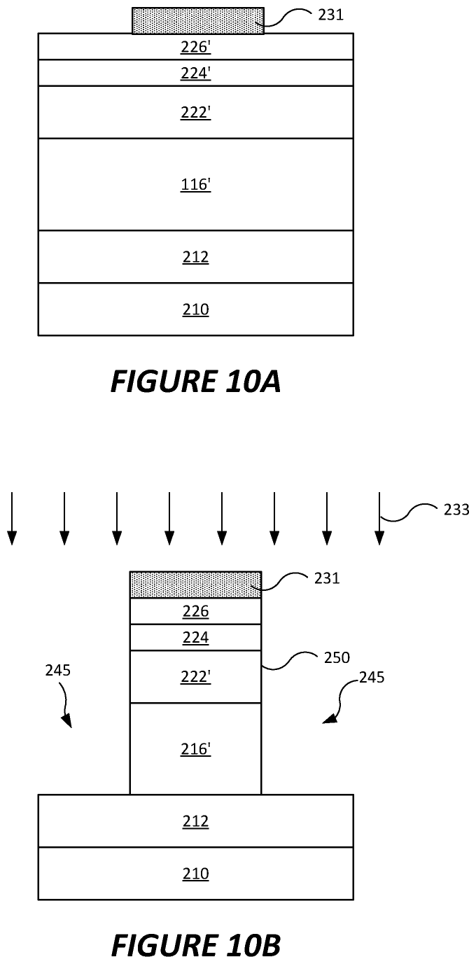

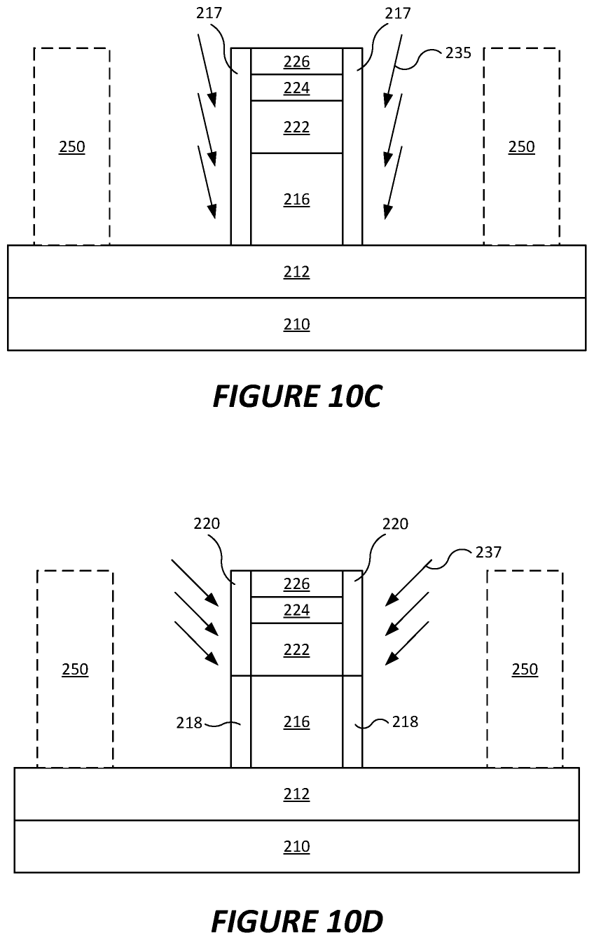

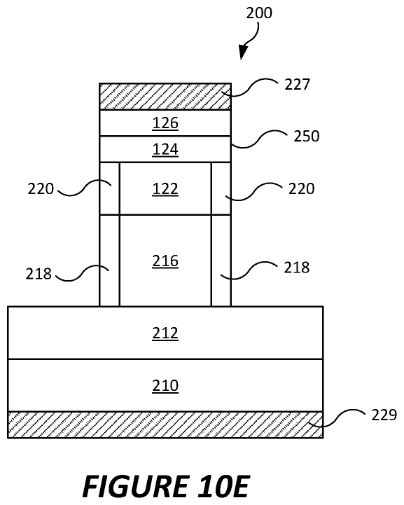

FIGS. 10A to 10E illustrate operations for forming a SiC JFET structure 100 according to some embodiments. Referring to FIG. 10A, a 4H-SiC substrate 210 is provided. The substrate 210 may be cut at an off-axis angle of about 3° to 5° away from the <0001> crystallographic direction.

An epitaxial layer structure is formed on the substrate 210, including an n-type 1-D region 212 and an n-type precursor layer 216′ that will form the drift region of the device. An n-type channel precursor layer 222′ is formed on the precursor layer 216′. An n+ source precursor layer 224′ and n++ contact precursor layer 226′ are formed on the channel precursor layer 222′. The n+ source precursor layer 224′ and n++ contact precursor layer 226′ may be formed, for example, by implantation of n-type dopants into the channel precursor layer 222′ using conventional methods.

The n-type 1-D region 212 may have a thickness of about 3 microns to 4 microns, and in some embodiments about 3.5 microns and a net doping concentration of about 8E15 cm-3 to 8E16 cm⁻³, in some embodiments about 3E16 cm-3 to 5E16 cm⁻³, and in some embodiments about 4E16 cm⁻³. The n-type precursor layer 216′ may have a thickness of about 3.5 microns to 4.5 microns, and in some embodiments about 4 microns, and a net doping concentration of about 5E16 cm3 to 5E17 cm⁻³, and in some embodiments about 2E17 cm⁻³. The n-type channel precursor layer 222′ may have a thickness of about 2 microns, and a net doping concentration of about 1E17 cm⁻³. The n+ source precursor layer 224′ may have a thickness of about 0.5 microns and a net doping concentration of about 1E18 cm⁻³. The n++ contact precursor layer 226′ may have a thickness of about 0.5 microns and a net doping concentration of greater than about 1E19 cm3. Together, the n+ source precursor layer 224′ and the n++ contact precursor layer 226′ may have a thickness of about 1 micron.

Referring to FIG. 10B, an etch mask 231 is formed on the n++ contact precursor layer 226′, and the n+ source precursor layer 224′, n++ contact precursor layer 226′ and channel precursor layer 222′ are anisotropically etched 233 using conventional methods, such as reactive ion etching or inductively coupled plasma etching, to define a mesa stripe 250 and trenches 245 adjacent the mesa stripe 250. Etching the structure to form the mesa stripe 250 defines an n+ source region 224 and an n++ contact region 226 in the mesa stripe 250. The mesa stripe 250 may have a width of about 1.2 microns.

Referring to FIG. 10C, p-type dopant ions 235 are implanted into the structure at a low angle relative to the normal direction to form p-type regions 213 in the n-type precursor layer 216′. For example, the p-type dopant ions 235 may be implanted at an angle of less than about 20 degrees, in some embodiments about 15 to 20 degrees, and in some embodiments about 15 to 18 degrees relative to the normal direction. The implanted ions 235 are implanted at an angle that is low enough that the implanted ions 235 are not substantially shadowed by adjacent mesa stripes 250, so that they are implanted into the entire sides of the mesa stripe 250. The p-type regions 213 are implanted with p-type dopants to have a net p-type doping concentration of about 5E16 cm-3 to 5E17 cm⁻³, and in some embodiments about 2E17 cm⁻³. This step defines the channel region 222 and the central n-type pillar 216 between the p-type regions 213.

Referring to FIG. 10D, p-type dopant ions 237 are implanted into the structure at a high angle relative to normal such that the implants are shadowed by neighboring mesa stripes 250 from reaching the lower portions of the mesa stripe 250. For example, the p-type dopant ions 237 maybe implanted at an angle of greater than about 20 degrees, and in some embodiments about 23 to 30 degrees and in some embodiments about 25 to 27 degrees, relative to the normal direction, and may reach about 3 microns down the mesa stripe 250, with the remainder of the mesa stripe 250 being shadowed by a neighboring mesa stripe 250. The implanted dopant ions 237 thereby form sidewall gate regions 220 in upper portions of the mesa stripe 250 and define p-type pillars 218 in the mesa stripe 250 adjacent the central n-type pillar 216. This defines the superjunction region 217 between the 1-D region 212 and the channel region 222.

In addition to being performed at a tilted angle relative to the wafer normal, the implantation of the p-type dopant ions 237 to form the sidewall gate regions 220 is performed at different twist or azimuthal angles, so that both opposing sidewalls and the ends of the mesa stripe 250 are implanted. This may be done using implantations at 0, 90, 180 and 270 degree twist angles.

Referring to FIG. 10E, a source contact 227 is formed on the n++ source contact region 226 and a drain contact 229 is formed on the backside of the substrate 210. Gate contacts (not shown) are formed to the sidewall gate regions 220 outside the plane of FIG. 10E to complete the JFET device structure 200.

While in the description above, the example embodiments are described with respect to semiconductor devices that have n-type substrates and channels in n-type portions of the drift layers, it will be appreciated that opposite conductivity type devices may be formed by simply reversing the conductivity of the n-type and p-type layers in each of the above embodiments. Thus, it will be appreciated that the present disclosure covers both n-type and p-type devices. It will likewise be appreciated that typically each power semiconductor device formed according to the ion implantation techniques disclosed herein will comprise a plurality of individual devices that are disposed in parallel in a unit cell structure.

Embodiments have been described above with reference to the accompanying drawings, in which embodiments are shown. It will be appreciated, however, that the inventive concepts may, however, be embodied in many different forms and should not be construed as limited to the embodiments set forth above. Rather, these embodiments are provided so that this disclosure will be thorough and complete, and will fully convey the scope of the inventive concepts to those skilled in the art. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present inventive concepts. The term “and/or” includes any and all combinations of one or more of the associated listed items.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the inventive concepts are described herein with reference to cross-section illustrations that are schematic illustrations of idealized embodiments (and intermediate structures) of the inventive concepts. The thickness of layers and regions in the drawings may be exaggerated for clarity. Additionally, variations from the shapes of the illustrations as a result, for example, of manufacturing techniques and/or tolerances, are to be expected.

Some embodiments are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation, the scope of the inventive concepts being set forth in the following claims.

1. A method of forming a semiconductor device, comprising:
providing a semiconductor substrate having a first conductivity type and having an epitaxial structure thereon, the epitaxial structure comprising a first region on the substrate, a second region on the first region, and a third region on the second region, wherein the first region, the second region, and the third region have the first conductivity type;
etching the epitaxial structure to form a mesa stripe and trenches on opposite sides of the mesa stripe, wherein the trenches extend through the third region and the second region to define a respective source region and channel region in the mesa stripe;
implanting first dopant ions having a second conductivity type, opposite the first conductivity type, through the trenches and into the first region to form second conductivity type pillars in the first region adjacent a central pillar region in the first region, wherein the second conductivity type pillars and the central pillar region form a superjunction drift region;
forming a source ohmic contact on a top of the mesa stripe; and
forming a drain ohmic contact on the substrate.

2. The method of claim 1, wherein implanting the first dopant ions comprises implanting the first dopant ions along a first crystallographic direction of the epitaxial structure along which implant channeling occurs in the epitaxial structure.

3. The method of claim 2, wherein the epitaxial structure comprises silicon carbide having a hexagonal crystal structure, and wherein the first crystallographic direction comprises a <0001> crystallographic direction.

4. The method of claim 3, wherein the first dopant ions are implanted at an implant energy of at least about 1.5 MeV.

5. The method of claim 3, wherein implanting the first dopant ions comprises implanting the first dopant ions through bottom surfaces of the trenches and into a portion of the first region beneath the trenches.

6. The method of claim 5, wherein the first dopant ions are implanted into the first region to a depth of at least about 2 microns below bottom surfaces of the trenches.

7. The method of claim 2, wherein the semiconductor substrate is cut at an off-axis angle relative to a direction normal to a growth surface of the semiconductor substrate toward a first direction, wherein the mesa stripe extends in the first direction.

8. The method of claim 7, wherein the first direction, the direction normal to the growth surface of the semiconductor substrate, and the <0001> crystallographic direction all lie in a same plane.

9. The method of claim 8, wherein the second conductivity type pillars comprise vertical regions in the first region that extend in the direction normal to the growth surface of the semiconductor substrate.

10. The method of claim 1, wherein etching the epitaxial structure comprises forming an etch mask on the third region and anisotropically etching the third region and the second region through the etch mask to form the trenches, wherein the etch mask is used as an implantation mask while implanting the first dopant ions into the first region to obstruct the first dopant ions from entering the mesa stripe.

11. The method of claim 1, wherein the epitaxial structure comprises a contact region on the third region, and wherein etching the epitaxial structure comprises etching the contact region, wherein the contact region has a higher doping concentration than the third region, and wherein the contact region obstructs the first dopant ions from penetrating deeper into the mesa stripe.

12. The method of claim 1, wherein the semiconductor device comprises a plurality of alternating mesa stripes and trenches that extend in a first direction along the semiconductor substrate and have respective opposing first and second ends, and wherein the alternating mesa stripes and trenches are spaced apart in a second direction that is perpendicular to the first direction.

13. The method of claim 12, wherein the mesa stripes become wider near the first and second ends thereof relative to middle portions of the mesa stripes.

14. The method of claim 12, wherein the trenches become narrower near the first and second ends thereof relative to middle portions of the trenches.

15. The method of claim 12, wherein the third region comprises a doped region that defines an active region of the semiconductor device within the doped region and a termination region of the semiconductor device outside the doped region.

16. The method of claim 15, wherein widths of the trenches increase in the second direction towards edges of the semiconductor device within the termination region of the semiconductor device.

17. The method of claim 15, wherein widths of the mesa stripes increase in the second direction towards the edges of the semiconductor device within the termination region of the semiconductor device.

18. The method of claim 1, further comprising:
implanting second dopant ions having the second conductivity type into sidewalls of the channel region to form sidewall gate regions on opposite sidewalls of the channel region.

19. The method of claim 18, wherein implanting the second dopant ions comprises implanting the second dopant ions at a tilted angle to form the sidewall gate regions in the channel region and in the second conductivity type pillars.

20. The method of claim 1, wherein the first conductivity type is n-type and the second conductivity type is p-type.

21. A method of forming a semiconductor device, comprising:
providing a semiconductor substrate having a first conductivity type and having an epitaxial structure thereon, the epitaxial structure comprising a first region on the substrate, a second region on the first region, and a third region on the second region, wherein the first region, the second region, and the third region have the first conductivity type;
etching the epitaxial structure to form a mesa stripe and trenches on opposite sides of the mesa stripe, wherein the trenches extend through the first region, the second region and the third region;
implanting first dopant ions having a second conductivity type, opposite the first conductivity type, into the mesa stripe through sidewalls of the trenches and into the first region to form second conductivity type pillars in the first region adjacent a central pillar region in the first region, wherein the second conductivity type pillars and the central pillar region form a superjunction drift region, and wherein implanting the first dopant ions is performed at a first implant angle relative to a normal direction that is perpendicular to a growth surface of the semiconductor substrate;
forming a source ohmic contact on a top of the mesa stripe; and
forming a drain ohmic contact on the substrate.

22. The method of claim 21, wherein the first implant angle is less than about 20 degrees.

23. The method of claim 21, further comprising:
implanting second dopant ions having the second conductivity type into upper sidewalls of the mesa stripe to form sidewall gate regions on opposite sidewalls of the second region;
wherein implanting the second dopant ions is performed at a second implant angle that is greater than the first implant angle.

24. The method of claim 23, wherein the second implant angle is greater than about 20 degrees.

25. The method of claim 23, wherein shadowing from adjacent mesa stripes on the semiconductor substrate obstructs the second dopant ions from being implanted into lower portions of the mesa stripe adjacent the first region.

26. The method of claim 21, wherein the first conductivity type is n-type and the second conductivity type is p-type.

27. The method of claim 21, wherein the semiconductor substrate comprises silicon carbide.

28. A semiconductor device, comprising:
a substrate; and
an epitaxial structure on the substrate, the epitaxial structure comprising:
a drift region; and
a mesa stripe on the drift region, the mesa stripe comprising a channel region on the drift region, a source region on the channel region, and sidewall gate regions on opposite sides of the channel region, wherein the channel region and the source region have a first conductivity type and the sidewall gate regions have a second conductivity type opposite the first conductivity type;
wherein the drift region comprises a superjunction region including a central pillar having the first conductivity type and outer pillars on opposite sides of the central pillar, wherein the outer pillars have the second conductivity type.

29. The semiconductor device of claim 28, wherein the drift region further comprises a first region beneath the central pillar and the outer pillars, the first region having the first conductivity type.

30. The semiconductor device of claim 28, wherein the central pillar and the outer pillars have a height of at least about 2 microns.

31. The semiconductor device of claim 31, wherein the epitaxial structure comprises a pair of trenches on opposite sides of the mesa, wherein the outer pillars are provided beneath respective ones of the trenches.

32. The semiconductor device of claim 28, wherein the sidewall gate regions are formed beneath respective ones of the trenches.

33. The semiconductor device of claim 28, wherein the semiconductor device comprises a plurality of alternating mesa stripes and trenches that extend in a first direction along the semiconductor substrate and have respective opposing first and second ends, and wherein the alternating mesa stripes and trenches are spaced apart in a second direction that is perpendicular to the first direction.

34. The semiconductor device of claim 33, wherein the mesa stripes become wider near the first and second ends thereof relative to middle portions of the mesa stripes.

35. The semiconductor device of claim 33, wherein the trenches become narrower near the first and second ends thereof relative to middle portions of the trenches.

36. The semiconductor device of claim 33, wherein the third region comprises a doped region that defines an active region of the semiconductor device within the doped region and a termination region of the semiconductor device outside the doped region.

37. The semiconductor device of claim 36, wherein widths of the trenches increase in the second direction towards edges of the semiconductor device within the termination region relative to widths of the trenches within the active region.

38. The method of claim 36, wherein widths of the mesa stripes increase in the second direction towards the edges of the semiconductor device within the termination region relative to widths of the mesa stripes within the active region.

39. The semiconductor device of claim 28, wherein the substrate comprises silicon carbide having a hexagonal polytype and having an off-cut angle towards a first direction relative to a crystallographic direction of the substrate along which implant channeling occurs, and wherein the mesa stripe extends in the first direction.

40. The semiconductor device of claim 39, wherein the crystallographic direction comprises a <0001> crystallographic direction.

41. A semiconductor device, comprising:
a substrate; and
a mesa on the substrate, the mesa comprising a drift region, a channel region on the drift region, and a source region on the channel region, wherein the channel region and the source region have a first conductivity type;
wherein the drift region comprises a superjunction region including a central pillar having the first conductivity type and outer pillars on opposite sides of the central pillar, wherein the outer pillars have a second conductivity type opposite the first conductivity type.

42. The semiconductor device of claim 41, wherein the mesa further comprises sidewall gate regions on opposite sides of the channel region, the sidewall gate regions having the second conductivity type.

43. The semiconductor device of claim 41, wherein the drift region further comprises a first region beneath the central pillar and the outer pillars, the first region having the first conductivity type.

44. The semiconductor device of claim 35, wherein the central pillar and the outer pillars have a height of at least about 2 microns.
